(19) United States
(12) Patent Application Publication
(10) Pub. No.: US 2014/0048782 A1
(43) Pub. Date: Feb. 20, 2014

(54) SPUTTERING TARGET AND ORGANIC LIGHT-EMITTING DISPLAY DEVICE INCLUDING BLACK MATRIX DEPOSITED THEREBY

(71) Applicant: Samsung Corning Precision Materials Co., Ltd., Gyeongsangbuk-do (KR)

(72) Inventors: Jin Woo Han, ChungCheongNam-Do (KR); Eui Soo Kim, ChungCheongNam-Do (KR); Seung Won Park, ChungCheongNam-Do (KR); Insung Sohn, ChungCheongNam-Do (KR); You Min Shin, ChungCheongNam-Do (KR)

(73) Assignee: SAMSUNG CORNING PRECISION MATERIALS CO., LTD., Gyeongsangbuk-do (KR)

(21) Appl. No.: 13/962,102

(22) Filed: Aug. 8, 2013

(30) Foreign Application Priority Data
Aug. 16, 2012 (KR) 10-2012-0089332

(51) Int. Cl. C23C 14/06; H01L 51/52

(52) U.S. Cl. CPC C23C 14/0688; H01L 51/5284
USPC 257/40; 204/298.13

(57) ABSTRACT

A sputtering target and an organic light-emitting display device including a black matrix deposited thereby. The sputtering target is used in a sputtering process for depositing a black matrix in an organic light-emitting display device. The sputtering target has a cermet structure in which a metal and a metal oxide are mixed.

### CROSS REFERENCE TO RELATED APPLICATION

The present application claims priority from Korean Patent Application Number 10-2012-0089332 filed on Aug. 16, 2012, the entire contents of which are incorporated herein for all purposes by this reference.

### BACKGROUND OF THE INVENTION

1. Field of the Invention

The present invention relates to a sputtering target and an organic light-emitting display device including a black matrix deposited thereby, and more particularly, to a sputtering target which has a cermet structure in which a metal and a metal oxide are mixed and an organic light-emitting display device including a black matrix deposited thereby.

2. Description of Related Art

In general, an organic light-emitting device (OLED) includes an anode, a light-emitting layer and a cathode. When a voltage is applied between the anode and the cathode, holes are injected from the anode into a hole injection layer and then migrate from the hole injection layer to the organic light-emitting layer via a hole transport layer, and electrons are injected from the cathode into an electron injection layer and then migrate from the electron injection layer to the light-emitting layer via an electron transport layer. Holes and electrons that have migrated into the light-emitting layer recombine with each other in the light-emitting layer, thereby generating excitons. When such excitons transit from the excited state to the ground state, light is emitted.

Organic light-emitting displays including an OLED are divided into a passive matrix type and an active matrix type depending on a mechanism that drives an N×M number of pixels which are arranged in the shape of a matrix.

In an active matrix type, a pixel electrode which defines a light-emitting area and a unit pixel driving circuit which applies a current or voltage to the pixel electrode are positioned in a unit pixel area. The unit pixel driving circuit has at least two thin-film transistors (TFTs) and one capacitor. Due to this configuration, the unit pixel driving circuit can supply a constant current irrespective of the number of pixels, thereby realizing uniform luminance. The active matrix type organic light-emitting display consumes little power, and thus can be advantageously applied to high definition displays and large displays.

However, since the organic light-emitting layer that is a component of the OLED is too thin, when an optical filter such as an elliptical polarizer is not attached to an organic light-emitting display device, external light is reflected from a cathode or an anode, thereby making it difficult for full blackness to be realized, which is problematic. In particular, an organic light-emitting display device that is commercially distributed at present employs an MM structure in which both a cathode and an anode are made of metal. This, however, makes the problem in which the contrast ratio is reduced due to reflection of the external light from an inside reflecting layer be more intense. Therefore, the organic light-emitting display device employs the optical filter such as an elliptical polarizer in order to prevent this problem.

The elliptical polarizer includes a linear polarizer and a phase difference plate. Although the elliptical polarizer serves to block external light, it also creates the problem of reducing light that is generated from inside. In addition, since the elliptical polarizer is fabricated by bonding the linear polarizer and the phase difference plate to each other, it is not only more expensive but also thicker than a typical optical filter. Accordingly, when the elliptical polarizer is applied to a flexible or foldable display, the linear polarizer and the phase difference plate may separate from each other or peel off from a circuit board, which is problematic.

In order to overcome this problem, studies for substituting the elliptical polarizer with a black matrix and an optical filter are underway.

However, unlike a liquid crystal display (LCD), the organic light-emitting display device uses a poly-Si thin-film transistor (TFT) which is crystallized using an excimer laser. However, there is a problem in that an organic black matrix of the related art does not withstand the crystallization process using the excimer laser. In addition, Cr and a Cr oxide (Cr₂₀₃) that were widely used in the black matrix of the related art are judged to be environmental pollutants, and it is difficult for these materials to be used any longer.

The information disclosed in the Background of the Invention section is provided only for better understanding of the background of the invention, and should not be taken as an acknowledgment or any form of suggestion that this information forms a prior art that would already be known to a person skilled in the art.

### BRIEF SUMMARY OF THE INVENTION

Various aspects of the present invention provide a sputtering target which has a cermet structure in which a metal and a metal oxide are mixed and an organic light-emitting display device including a black matrix deposited thereby.

In an aspect of the present invention, provided is a sputtering target that is used in a sputtering process for depositing a black matrix in an organic light-emitting display device. The sputtering target has a cermet structure in which a metal and a metal oxide are mixed.

According to an exemplary embodiment of the present invention, the metal may be at least one selected from the group consisting of Mo, Si, W, Mn and Co.

The metal oxide may be a combination of at least one selected from the group consisting of Mo, Si, W, Mn and Co with O.

In another aspect of the present invention, provided is a organic light-emitting display device that includes a substrate having defined thereon a first area and a second area; a black matrix formed on the second area; an insulating layer formed on the first area and the black matrix; an organic light-emitting device (OLED) formed on the insulating layer corresponding to the first area; and a thin-film transistor formed on the insulating layer corresponding to the second area. The black matrix has a cermet structure in which a metal and a metal oxide are mixed.

According to an exemplary embodiment of the present invention, the metal may be at least one selected from the group consisting of Mo, Si, W, Mn and Co.

The metal oxide may be a combination of one selected from the group consisting of Mo, Si, W, Mn and Co with O.

The organic light-emitting display device may have a bottom emission structure.

According to embodiments of the present invention, since the sputtering target having a cermet structure in which a metal and a metal oxide are mixed is used, it is possible to prevent oxidation and degassing during high temperature processing unlike an organic black matrix of the related art. Since it is possible to produce a black matrix having a high resistance and a low reflectance, the elliptical polarizer that has been used in the related art can be omitted, and parasitic capacitance that occurs from an interference-type black matrix of the related art can be reduced.

The methods and apparatuses of the present invention have other features and advantages which will be apparent from, or are set forth in greater detail in the accompanying drawings, which are incorporated herein, and in the following Detailed Description of the Invention, which together serve to explain certain principles of the present invention.

### BRIEF DESCRIPTION OF THE DRAWINGS

FIG. 1 is a cross-sectional view showing an organic light-emitting display device according to an embodiment of the present invention.

### DETAILED DESCRIPTION OF THE INVENTION

Reference will now be made in detail to a sputtering target and an organic light-emitting display device including a black matrix deposited thereby according to the present invention, embodiments of which are illustrated in the accompanying drawings and described below, so that a person having ordinary skill in the art to which the present invention relates can easily put the present invention into practice.

Throughout this document, reference should be made to the drawings, in which the same reference numerals and signs are used throughout the different drawings to designate the same or similar components. In the following description of the present invention, detailed descriptions of known functions and components incorporated herein will be omitted when they may make the subject matter of the present invention unclear.

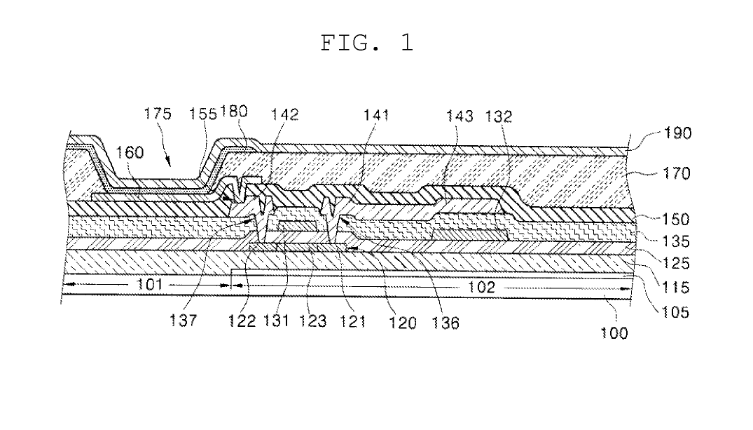

As shown in FIG. 1, the sputtering target according to an embodiment of the present invention is a target that is used in a sputtering process for depositing a black matrix 105 which serves to block external light in an organic light-emitting display device. The present invention is not limited to an organic light-emitting display device having the structure as in FIG. 1, and an organic light-emitting display device according to the present invention can have other various structures. Here, the sputtering is a method of releasing particles from the target by striking plasma particles to the target at a high speed so that the particles from the target are deposited on a substrate 100 which is positioned opposite the target. Accordingly, the material that is deposited by the target is identical with the material that constitutes the target.

According to an embodiment of the present invention, the sputtering target can have a cermet structure in which a metal and a metal oxide are mixed. Here, examples for the metal that constitutes the cermet structure may include Mo, Al, Ag, Fe, Co, Mn, Ni, Cu, Zr, W, Cr, Si, Sn and the like, except for C-based materials that constitute an organic black matrix of the related art. However, it is difficult to use Cr in a commercially distributed product because of its harmfulness, and it is difficult to apply Ni to a direct-current (DC) magnetron sputter that is widely used in a large target fabrication line since it is magnetic. Therefore, optimum metal elements that are usable are selected according to an embodiment of the present invention. Specifically, according to an embodiment of the present invention, examples for the metal that constitutes the cermet structure may be at least one selected from among Mo, Si, W, Mn and Co. In addition, the metal oxide that constitutes the cermet structure can be a combination of one selected from among Mo, Si, W, Mn and Co with O. Considering the relationship between the metals and the metal oxides as above, the cermet structure can have one structure selected from among, for example, Mo—MoO, Mo—Si—O, W—Si—O, Mo—W—O, Mo—W—Si—O, Co—Mo—O and Co—Mn—Si—O.

When the sputtering target having the cermet structure in which a metal and a metal oxide are mixed is produced and the black matrix 105 is deposited on the substrate 100 of the organic light-emitting display device by sputtering, it is possible to prevent oxidation and degassing during hot processing unlike the organic black matrix of the related art, preclude the elliptical polarizer of the related art by forming the black matrix that has a high resistance and a low reflectance, and reduce parasitic capacitance that occurs in the interference-type black matrix of the related art.

The sputtering target can be fabricated by mixing the metal and the metal oxide powder, molding the mixture by a molding method, such as cold pressing, slip casting, filter pressing, cold isostatic pressing, gel casting, centrifugal sedimentation or gravimetric sedimentation, and then sintering the resultant compact. Furthermore, the target fabricated in this fashion can be used in a sputtering process in the state in which it is bonded to and supported by a backing plate made of a metal material.

In addition, as shown in FIG. 1, the organic light-emitting display device includes the substrate 100, the black matrix 105 which is deposited using the sputtering target according to an embodiment of the present invention, an insulating layer 115, an organic light-emitting device (OLED) and a thin-film transistor (TFT). Here, the organic light-emitting display device has a bottom emission structure.

The substrate 100 has defined thereon a first area 101 on which the OLED is to be formed and a second area 102 on which the TFT is to be formed.

The black matrix 105 is formed on the second area 102 of the substrate 100, except for the first area 101 on which the OLED is to be formed. The black matrix 105 is deposited on the substrate 100 using the sputtering target that has the cermet structure in which a metal and a metal oxide are mixed.

The insulating layer 115 is formed on the black matrix 105 and the first area 101 of the substrate 100. The TFT which includes a semiconductor layer 120 having source and drain areas 121 and 122, a gate electrode 131 formed on top of the semiconductor layer 120, source and drain electrodes 141 and 142 in contact with the source and drain areas 121 and 122 via contact holes 136 and 137 is formed on a part of the insulating layer 115 that is positioned on the second area 102.

In addition, a capacitor having a first electrode 132 which is made of the same material as the gate electrode 131 and a second electrode 143 which is connected to one of the source and drain electrodes 141 and 142, for example, the source electrode 141, is formed on the second area 102. In addition, a gate insulating layer 125 is formed between the semiconductor layer 120 and the gate electrode 131 and between the semiconductor layer 120 and the first electrode 132, and an interlayer insulating layer 135 is formed between the gate electrode 131 and the source and drain electrodes 141 and 142 and between the first electrode 132 and the second electrode 143.

A protective film 150 having a via 155 which exposes a part of one of the source and drain electrodes 141 and 142, for example, a part of the drain electrode 142, is formed in front with respect to the substrate 100. A pixel electrode 160 which contacts the drain electrode 142 through the via 155 is formed on the protective film 150.

A planarization film 170 having an opening 175 through which the pixel electrode 160 is exposed is formed on the protective film 150 and the pixel electrode 160. An organic light-emitting layer 180 and a cathode 190 are formed on the planarization film 170, thereby producing the OLED having the pixel electrode 160 as an anode.

The OLED has a multilayer structure which includes the pixel electrode 160, or the anode, the organic light-emitting layer 180 and the cathode 190. The pixel electrode 160 can be made of a metal or oxide, such as Au, In, Sn or indium-doped tin oxide (ITO), which has a large work function in order to facilitate hole injection. The cathode 190 can be made of a metal thin film of Al, Al:Li or Mg:Ag which has a small work function in order to facilitate electron injection. The organic light-emitting layer 180 is formed such that it includes a hole injection layer, a hole transport layer, an emissive layer, an electron transport layer and an electron injection layer which are sequentially stacked on the pixel electrode 160. According to this configuration, when a forward voltage is induced between the pixel electrode 160 and the cathode 190, electrons from the cathode 190 migrate to the emissive layer through the electron injection layer and the electron transport layer, and holes from the pixel electrode 160 migrate to the emissive layer through the hole injection layer and the hole transport layer. Electrons and holes that are injected into the organic light-emitting layer 180 recombine with each other in the organic light-emitting layer 180, thereby generating excitons. When such excitons transit from the excited state to the ground state, light is emitted. In this case, the brightness of emitted light is proportional to the amount of current that flows between the pixel electrode 160 and the cathode 190.

The foregoing descriptions of specific exemplary embodiments of the present invention have been presented with respect to the drawings. They are not intended to be exhaustive or to limit the present invention to the precise forms disclosed, and obviously many modifications and variations are possible for a person having ordinary skill in the art in light of the above teachings.

It is intended therefore that the scope of the present invention not be limited to the foregoing embodiments, but be defined by the Claims appended hereto and their equivalents.

What is claimed is:

1. A sputtering target used in a sputtering process for depositing a black matrix in an organic light-emitting display device, the sputtering target having a cermet structure in which a metal and a metal oxide are mixed.

2. The sputtering target of claim 1, wherein the metal comprises at least one selected from the group consisting of Mo, Si, W, Mn and Co.

3. The sputtering target of claim 1, wherein the metal oxide comprises a combination of at least one selected from the group consisting of Mo, Si, W, Mn and Co with O.

4. An organic light-emitting display device comprising:
a substrate having defined thereon a first area and a second area;
a black matrix formed on the second area;
an insulating layer formed on the first area and the black matrix;
an organic light-emitting device formed on the insulating layer corresponding to the first area; and
a thin-film transistor formed on the insulating layer corresponding to the second area,
wherein the black matrix has a cermet structure in which a metal and a metal oxide are mixed.

5. The organic light-emitting display device of claim 4, wherein the metal comprises at least one selected from the group consisting of Mo, Si, W, Mn and Co.

6. The organic light-emitting display device of claim 4, wherein the metal oxide comprises a combination of one selected from the group consisting of Mo, Si, W, Mn and Co with O.

7. The organic light-emitting display device of claim 4, having a bottom emission structure.
